(19) United States
(12) Patent Application Publication
(10) Pub. No.: US 2013/0030729 A1
(43) Pub. Date: Jan. 31, 2013

(54) MOTHERBOARD ALARM SYSTEM TEST CIRCUIT

(71) Applicants: YI-XIN TU, Shenzhen City (CN); GUO-FENG ZHANG, Shenzhen City (CN); ZHENG-QUAN PENG, Shenzhen City (CN); HAI-QING ZHOU, Shenzhen City (CN)

(72) Inventors: YI-XIN TU, Shenzhen City (CN); GUO-FENG ZHANG, Shenzhen City (CN); ZHENG-QUAN PENG, Shenzhen City (CN); HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/415,849

(22) Filed: Mar. 9, 2012

(30) Foreign Application Priority Data
Jul. 29, 2011 (CN) 201110215724.4

(51) Int. Cl. G01R 31/00

(52) U.S. Cl. 702/58

(57) ABSTRACT

A motherboard alarm system test circuit includes an infrared emitter, a memory, and a circuit board. The circuit board includes a memory slot, many edge connectors, an infrared receiver, a single chip computer, and a switch circuit. The memory slot includes many spaced metal sheets. One end of each metal sheet is electrically connected to one of the first golden fingers of the memory. Each edge connector is electrically connected to the other end of each metal sheet. The second golden fingers of the circuit board are electrically connected to the memory slot. The signal chip computer includes an input pin electrically connected to the infrared receiver. The switch circuit is electrically connected to the signal chip computer. The switch circuit controls an electrical connection between the plurality of metal sheets and the plurality of first golden fingers of the memory.

### BACKGROUND

1. Technical Field

The present disclosure relates to motherboard alarm systems, and particularly, to a motherboard alarm system test circuit.

2. Description of Related Art

In a process of testing a computer, testing a motherboard alarm system is a very important test. For example, when a fault occurs in a memory of a motherboard, a loudspeaker of the motherboard will sound an alarm, or an indicator light of the motherboard will illuminate.

When the motherboard alarm system is tested, a particular connection of the memory is manually grounded via wires, to set the connection at a low level voltage. In such case, a fault will occur in the memory. If the motherboard alarm system outputs an alarm in this case, the motherboard alarm system is in a normal state. If the motherboard alarm system does not output an alarm, the motherboard alarm system is in an abnormal state, and the motherboard alarm system needs to be checked and repaired. In addition, another connection of the memory should be manually grounded to verify whether the previous test result is right. The above test method needs to ground a golden finger of the memory by hand. Therefore, it is very complicated, and incorrect operation often occurs

Therefore, what is needed is a new motherboard alarm system test circuit that can overcome the described limitations.

### BRIEF DESCRIPTION OF THE DRAWINGS

FIG. 1 is an assembly isometric view of a circuit board of a motherboard alarm system test circuit, a motherboard waiting for testing, and a memory for facilitating the test according to an exemplary embodiment.

FIG. 2 is an exploded isometric view of the circuit board of the motherboard alarm system test circuit, the motherboard waiting for testing, and the memory for facilitating the test of FIG. 1.

FIG. 3 is one embodiment of a switch circuit on the circuit board of FIG. 1.

### DETAILED DESCRIPTION

Embodiments will be described with reference to the drawings.

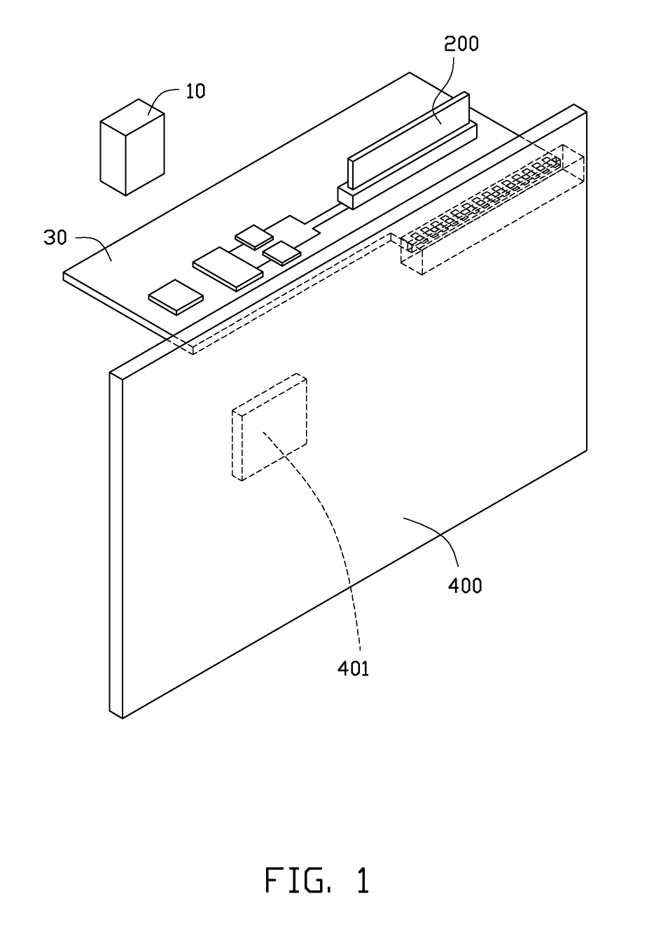

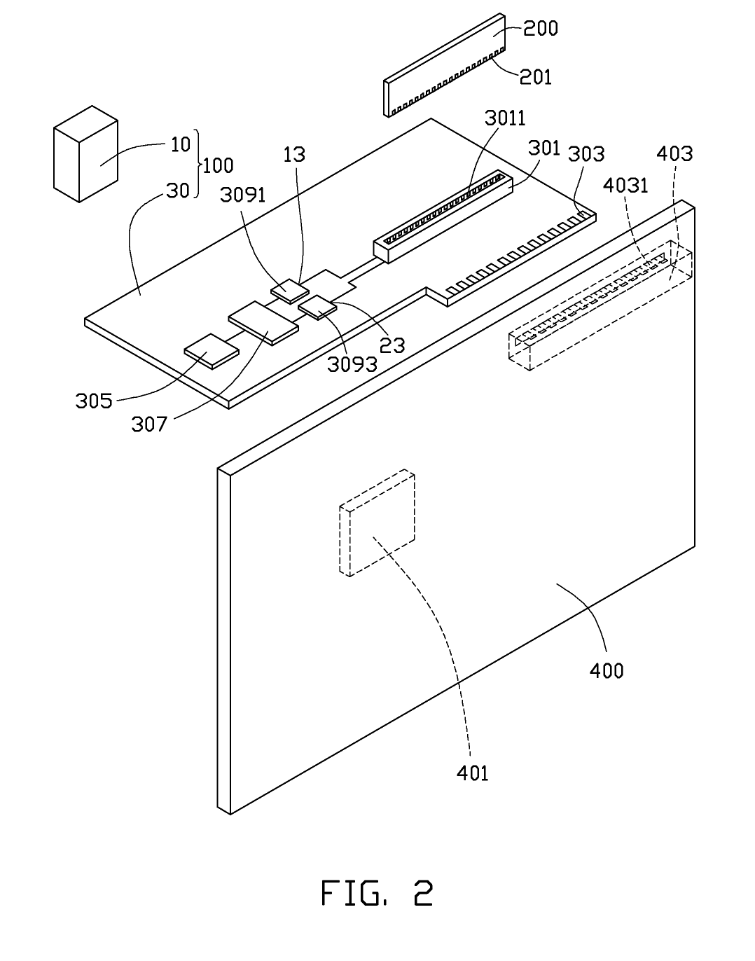

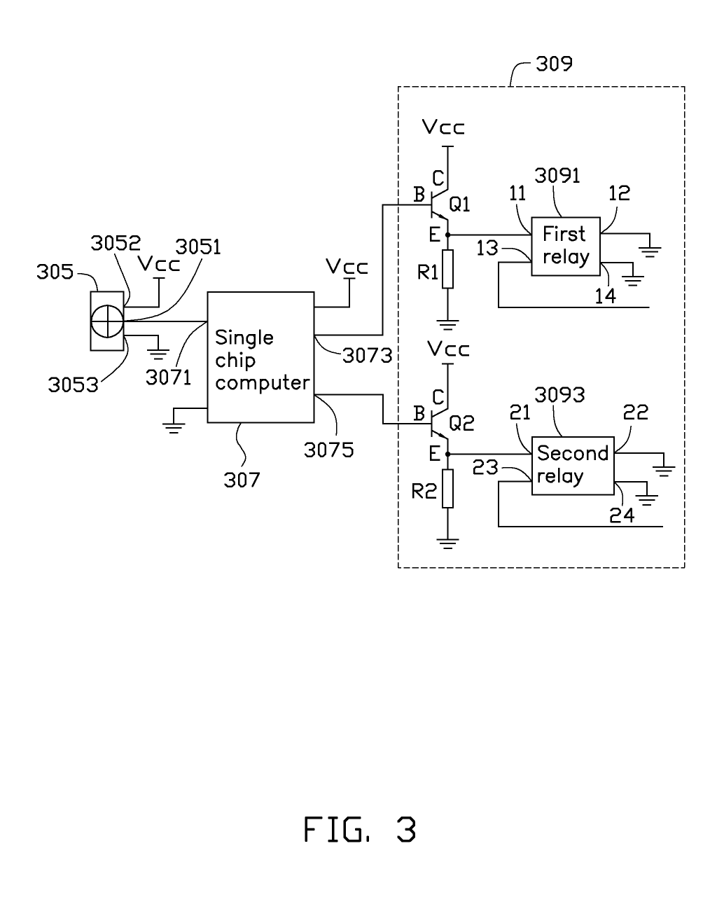

Referring to FIGS. 1, 2 and 3, a motherboard alarm system test circuit 100, in accordance with an exemplary embodiment, is shown. The motherboard alarm system test circuit 100 is configured for testing a memory alarm system 401 of a motherboard 400. The motherboard alarm system test circuit 100 includes an infrared emitter 10, and a circuit board 30, and a memory 200 having a plurality of edge connectors (first golden fingers 201).

The infrared emitter 10 is configured for emitting infrared light, and includes two control buttons (not shown). When one of the two control buttons is actuated, the infrared emitter 10 emits a first infrared light. When the other control button is actuated, the infrared emitter 10 emits a second infrared light.

The circuit board 30 includes a memory slot 301, a plurality of edge connectors (second golden fingers 303), an infrared receiver 305, a signal chip computer 307 electrically connected to the infrared receiver 305, and a switch circuit 309 electrically connected to the signal chip computer 307.

The memory slot 301 includes a plurality of spaced metal sheets 3011. A first end of each metal sheet 3011 is electrically connected to a single edge connector (first golden finger 201) of the memory 200. A second end of each metal sheet 3011 is electrically connected to a single edge connector of the second golden fingers 303 of the circuit board 30 via electrical wires (not shown).

Each of the second golden fingers 303 is electrically connected to one of the metal sheets 4031 of a memory slot 403 of the motherboard 400.

The infrared receiver 305 is configured for receiving the first infrared emission emitted by the infrared emitter 10, and converting the first infrared emission into a first electrical signal. In the present embodiment, the infrared receiver 305 is an infrared receiving head, and includes a first pin 3051, a second pin 3052, and a third pin 3053. The first pin 3051 is electrically connected to the signal chip computer 307. The second pin 3052 is electrically connected to a power source (e.g., 5.5V). The third pin 3053 is grounded.

The signal chip computer 307 includes an input pin 3071 electrically connected to the first pin 3051, and a first output pin 3073. The input pin 3071 is configured for receiving the first electrical signal.

The switch circuit 309 includes a first relay 3091. The first relay 3091 includes a first pin 11, a second pin 12, a third pin 13, and a fourth pin 14. The first pin 11 is electrically connected to the second input pin 3073 of the signal chip computer 307. The third pin 13 is electrically connected to a metal sheet 3011 via electrical wires (not shown), such that the third pin 13 is electrically connected to a first golden finger 201 of the memory 200. The second pin 12 and the fourth pin 14 are grounded.

In testing the memory alarm system 401 of the motherboard 400, the circuit board 30 with the memory 200 is inserted into the memory slot 403. A control button of the infrared emitter 10 is actuated, such that a first infrared light is emitted by the infrared emitter. When the first infrared light is received by the infrared receiver 305, the first infrared light is converted into a first electrical signal by the infrared receiver 305, and is transmitted to the signal chip computer 307. When the first electrical signal is received by the single chip computer 307, the signal chip computer 307 will cause a first high level signal (e.g., logic 1) at the first output pin 3073, such that the first pin 11 of the first relay 3091 is set at a high level voltage. Then, the first relay 3091 causes an electrical connection to be made between the third pin 13 and the fourth pin 14 as the connection is closed. In such case, the metal sheet 3011 electrically connected to the third pin 13 is grounded.

When the metal sheet 3011 electrically connected to the third pin 13 is grounded, a first golden finger 201 of the memory 200 is grounded, and the memory 200 will cease working. In such case, if the memory alarm system 401 outputs an alarm, the memory alarm system 401 is in a normal state; if the memory alarm system 401 does not sound an alarm, the memory alarm system 401 is in an abnormal state, and the memory alarm system 401 must be checked and repaired.

In the present embodiment, the motherboard alarm system test circuit 100 tests the memory alarm system 401 of the motherboard 400 by inserting the circuit board 30 carrying the memory 200 into the memory slot 403 and then actuating a control button of the infrared emitter 10. Therefore, there is no need to manually ground the first golden finger 201 of the memory 200 via wires to test the memory alarm system 401, and testing efficient can be improved.

In order to augment the power of the first high level voltage output by the first output pin 3073 and ensure the first relay 3091 is driven to work, in the present embodiment, the switch circuit 309 also includes a BJT Q1 (bipolar junction transistor) electrically connected between the signal chip computer 307 and the first relay 3091. The BJT Q1 amplifies the first high level voltage to drive the first relay 3091 to work. The base electrode B of the BJT Q1 is electrically connected to the first output pin 3073. The emitter electrode E of the BJT Q1 is electrically connected to the first pin 11. The collector electrode C of the BJT Q1 is electrically connected to a 3.3V power source. In other embodiments, a high-efficiency or low-power relay as the first relay 3091 avoids the need for the BJT Q1 may be omitted.

In order to prevent over-current flow from damaging the BJT Q1, in the present embodiment, the switch circuit 309 also includes a resistor R1. One end of the resistor R1 is grounded, and the other end of the resistor R1 is electrically connected to the emitter electrode E of the BJT Q1. In other embodiments, if a large current flow will not damage the BJT Q1, the resistor R1 becomes redundant.

In order to verify whether the memory alarm system 401 is itself working normally or abnormally, in the present embodiment, the signal chip computer 307 also includes a second output pin 3075, and the switch circuit 309 also includes a second relay 3093 electrically connected to the second output pin 3075. The second relay 3093 includes a fifth pin 21, a sixth pin 22, a seventh pin 23, and an eighth pin 24. The fifth pin 21 is electrically connected to the second output pin 3075. The seventh pin 23 is electrically connected to another individual metal sheet of the metal sheets 3011 of the memory slot 301, such that the seventh pin 23 is electrically connected to another single first golden finger 201 of the memory 200. The sixth pin 22 and the eighth pin 24 are grounded.

When the motherboard alarm system test circuit 100 verifies whether the memory alarm system 401 is in a normal state or in an abnormal state, the other control button of the infrared emitter 10 is actuated, such that a second infrared light is emitted by the infrared emitter. When the second infrared light is received by the infrared receiver 305, the second infrared light is converted into a second electrical signal by the infrared receiver 305, and is transmitted to the signal chip computer 307. When the second electrical signal is received by the single chip computer 307, the signal chip computer 307 will cause a high level signal (e.g., logic 1) at the second output pin 3075, such that the fifth pin 21 of the second relay 3093 is set at a high level voltage. Then, the second relay 3093 will work, and an electrical connection made between the seventh pin 23 and the eighth pin 24 as the gap is closed. In such case, the metal sheet 3011 electrically connected to the seventh pin 23 is grounded.

When the metal sheet 3011 electrically connected to the seventh pin 23 is grounded, a first golden finger 201 of the memory 200 is grounded, and the memory 200 ceases to work. In such case, if the memory alarm system 401 sounds an alarm, the memory alarm system 401 is in a normal state; if the memory alarm system 401 does not sound an alarm, it is the memory alarm system 401 itself which is in an abnormal state, and the memory alarm system 401 must be repaired or replaced.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A motherboard alarm system test circuit for testing a memory alarm system of a motherboard comprising:
an infrared emitter for emitting a first infrared light,
a memory, the memory comprising a plurality of first golden fingers, and
a circuit board, comprising:
a memory slot, the memory slot comprising a plurality of spaced metal sheets, a first end of each of the metal sheets electrically connected to one of the first golden fingers of the memory;
a plurality of second golden fingers, each of the second golden fingers electrically connected to a second end of each of the metal sheets, the second golden fingers of the circuit board electrically connected to the memory slot of the motherboard;
an infrared receiver for receiving the first infrared light;
a single chip computer, the single chip computer comprising an input pin electrically connected to the infrared receiver; and
a switch circuit electrically connected to the signal chip computer, the switch circuit controlling an electrical connection between the plurality of metal sheets and the plurality of first golden fingers of the memory.

2. The motherboard alarm system test circuit of claim 1, wherein the signal chip computer further comprises a first output pin, the switch circuit comprises a first relay, the first relay comprises a first pin electrically connected to the first output pin, a third pin, and a fourth pin, the third pin of the first relay is electrically connected to one of the metal sheets of the circuit board, such that the third pin of the first relay is electrically connected to one of the first golden fingers of the memory, the fourth pin is grounded.

3. The motherboard alarm system test circuit of claim 2, wherein the first infrared light emitted is received by the infrared receiver, and a first electrical signal indicative of the infrared light is sent to the single chip computer via the input pin.

4. The motherboard alarm system test circuit of claim 3, wherein the single chip computer controls to output a high level signal at the first output pin according to the first electrical signal, such that the first pin of the first relay is set at a high level voltage, and the third pin of the first relay is electrically connected to the fourth pin of the first relay causing the metal sheet that is electrically connected to the third pin of the first relay to be grounded, and one of the first golden fingers of the memory to be grounded.

5. The motherboard alarm system test circuit of claim 4, wherein when one of the first golden fingers of the memory is grounded, the memory ceases working, if the memory alarm system alarm, the memory alarm system is in a normal state.

6. The motherboard alarm system test circuit of claim 4, wherein when one of the first golden fingers of the memory is grounded, the memory ceases working, if the memory alarm system does not alarm, the memory alarm system is in an abnormal state.

7. The motherboard alarm system test circuit of claim 4, wherein the signal chip computer further comprises a second output pin, the switch circuit further comprises a second relay, the second relay comprises a fifth pin electrically connected to the second output pin, a seventh pin, and a eighth pin, the seventh pin of the second relay is electrically connected to another individual metal sheet of the memory slot of the circuit board, such that the seventh pin of the second relay is electrically connected to the another individual golden finger of the memory, the eighth pin of the second relay is grounded.

8. The motherboard alarm system test circuit of claim 7, wherein when the emitter emits a second infrared light, the first infrared light emitted is received by the infrared receiver, and a second electrical signal indicative of the second infrared light is sent to the single chip computer.

9. The motherboard alarm system test circuit of claim 8, wherein the single chip computer controls to output a high level signal at the second output pin according to the second electrical signal, such that the fifth pin of the second relay is set at a high level voltage, and the seventh pin of the second relay is electrically connected to the eighth pin of the second relay causing the metal sheet that is electrically connected to the seventh pin of the second relay to be grounded, and one of the first golden fingers of the memory to be grounded.

10. The motherboard alarm system test circuit of claim 9, wherein when one of the first golden fingers of the memory is grounded, a fault occurs in the memory, if the memory alarm system alarm, the memory alarm system is in a normal state.

11. The motherboard alarm system test circuit of claim 9, wherein when one of the first golden fingers of the memory is grounded, a fault occurs in the memory, if the memory alarm system does not alarm, the memory alarm system is in an abnormal state.

12. The motherboard alarm system test circuit of claim 1, wherein the switch circuit further comprises a BJT electrically connected to the first relay, a base electrode of the BJT is electrically connected to the first output pin, a collector electrode of the BJT is electrically connected to a power source, and an emitter electrode of the BJT is electrically connected to the first pin of the first relay.
